(19) United States
(12) Patent Application Publication
(10) Pub. No.: US 2011/0005573 A1
(43) Pub. Date: Jan. 13, 2011

(54) FOLDABLE SOLAR ENERGY APPARATUS

(75) Inventors: Chung-Min CHANG, Jhubei City (TW); Canny CHENG, Jhubei City (TW); Ching-Hui YU, Jhubei City (TW); Chih-Chen CHEN, Jhubei City (TW)

Correspondence Address: STITES & HARBISON PLLC, Suite 900, 1199 N. Fairfax Street, Alexandria, VA, 22314, US

(73) Assignee: Power Light Tech. Co., Ltd., Jhubei City (TW)

(21) Appl. No.: 12/540,560

(22) Filed: Aug. 13, 2009

(30) Foreign Application Priority Data
Jul. 7, 2009 (TW) 098122962

(51) Int. Cl. H01L 31/045

(52) U.S. Cl. 136/245

(57) ABSTRACT

A foldable solar energy apparatus is provided. The foldable solar energy apparatus includes a frame, a first solar energy module, an actuation module, and a power module. A photovoltaic panel is coupled to a first holder of the first solar energy module, and electricity generated by the photovoltaic panel is stored in the power module. The first holder is rotatably coupled to the frame so that the first holder is collapsible via the actuation module, which is disposed at the frame and connected to the first holder. The first holder and the actuation module provide the solar energy apparatus with a foldable function. Thus, the solar energy apparatus can be folded in response to changes in weather conditions, thereby preventing the photovoltaic panel from being damaged by bad weather.

### BACKGROUND OF THE INVENTION

1. Technical Field

The present invention relates to a foldable solar energy apparatus and, more particularly, to a foldable solar energy apparatus applicable to a solar power generator.

2. Description of Related Art

In view of global warming caused by the greenhouse effect and the various impacts of global warming, environmental awareness is on the rise, and international environmental conventions were successively signed to reduce carbon dioxide emissions. Hence, many countries are now devoted to the research of alternative energy sources that are capable of replacing traditional fossil fuels.

As an inexhaustible pollution-free energy source, solar energy is both economical and environment-friendly. Therefore, government efforts around the world have been directed to promoting applications powered by solar energy. Solar energy is not only useful in fulfilling our daily electricity demand, but also applicable to the automobile industry, for example. In the latter case, cars are designed to be driven by solar energy instead of gasoline, thereby significantly lowering carbon dioxide emissions.

For photovoltaic panels to absorb solar energy efficiently, it is necessary to install photovoltaic panels in an open space where long-term exposure to the sun is attainable. Besides, most photovoltaic panels have large surface areas so as to increase solar energy absorption efficiency. However, such design also makes photovoltaic panels bulky and difficult for storage. Therefore, when the weather is inclement, such as when a typhoon strikes, the wind acting on the large wind load area of photovoltaic panels tends to render the panels unstable or even blow the panels down, thus causing damage and shortening the service life of the panels.

Taiwan Patent No. M311007 discloses a foldable photovoltaic panel comprising a plurality of substrates, wherein each of the substrates has a top surface formed as a light-receiving surface. In addition, flexible plates are provided between adjacent substrates such that the substrates are interconnected and can be folded upon one another.

The photovoltaic panel disclosed in the above-cited patent can be folded so as to have its volume reduced for easy transportation. However, such a manual folding design is not applicable to very large photovoltaic panels or to a large number of photovoltaic panels.

### BRIEF SUMMARY OF THE INVENTION

The present invention provides a foldable solar energy apparatus wherein a solar energy module is rotatable by means of pivot units operating in conjunction with an actuation module, such that the solar energy module is collapsible when needed.

The present invention provides a foldable solar energy apparatus wherein a solar energy module is collapsible under control of an actuation module. Therefore, with the actuation module, even a large solar energy module is easily collapsible.

The present invention provides a foldable solar energy apparatus wherein a solar energy module is collapsible to reduce a wind load area thereof. Thus, the solar energy module can be collapsed in response to changes in weather conditions so as to avoid damage.

In order to achieve the above and other effects, the present invention provides a foldable solar energy apparatus including a frame, at least one solar energy module, an actuation module, and a power module. The frame includes at least one first pivot unit coupled to a top portion of the frame. Each first solar energy module includes a first holder and at least one photovoltaic panel. Each first holder has a first surface and a second surface opposite the first surface. Each first holder also includes a second pivot unit provided at a first lateral surface of the first holder and rotatably coupled to the corresponding first pivot unit. The at least one photovoltaic panel of each first solar energy module is coupled to the first surface of the corresponding first holder. The actuation module is provided at the frame and connected to the first surface of each first holder, thus allowing each first holder to move between a first position and a second position. The power module includes an electricity storage unit electrically connected to the at least one photovoltaic panel of each first solar energy module so as to store electricity. The power module also includes a control unit connected in electrical signal communication with the electricity storage unit so as to control charging/discharging of the electricity storage unit and drive the actuation module.

In order to achieve the above and other effects, the present invention also provides a foldable solar energy apparatus including a frame, a third solar energy module, a fourth solar energy module, an actuation module, and a power module. The third solar energy module includes a third holder and at least one photovoltaic panel. The third holder has a fifth surface coupled to a top portion of the frame and a sixth surface opposite the fifth surface. The third holder also includes at least one fourth pivot unit provided at a fourth lateral surface and a fifth lateral surface of the third holder, respectively, wherein the fourth lateral surface is opposite the fifth lateral surface. The at least one photovoltaic panel of the third solar energy module is coupled to the sixth surface. The fourth solar energy module includes a fourth holder and at least one photovoltaic panel. The fourth holder has a seventh surface and an eighth surface opposite the seventh surface. The fourth holder also includes a fifth pivot unit provided at a sixth lateral surface of the fourth holder and rotatably coupled to the corresponding fourth pivot unit. The at least one photovoltaic panel of the fourth solar energy module is coupled to the eighth surface. The actuation module is provided at the frame and connected to the seventh surface, thus allowing the fourth holder to move between a first position and a second position. The power module includes an electricity storage unit electrically connected to the photovoltaic panels so as to store electricity. The power module also includes a control unit connected in electrical signal communication with the electricity storage unit so as to control charging/discharging of the electricity storage unit and drive the actuation module.

Implementation of the present invention at least involves the following inventive steps:

1. As the solar energy module is collapsed under control of the actuation module, even a large solar energy module can be collapsed with ease.

2. With the solar energy module being collapsible, the solar energy apparatus can be folded in response to changes in weather conditions, so as not to be damaged by inclement weather.

### BRIEF DESCRIPTION OF THE SEVERAL VIEWS OF THE DRAWINGS

The invention as well as a preferred mode of use, further objectives, and advantages thereof will be best understood by referring to the following detailed description of illustrative embodiments in conjunction with the accompanying drawings, wherein:

FIG. 1A is a perspective view of a foldable solar energy apparatus according to a first embodiment of the present invention;

FIG. 1B is a perspective view showing another aspect of the foldable solar energy apparatus according to the first embodiment of the present invention;

FIG. 2 is a perspective view showing operation of the foldable solar energy apparatus according to the first embodiment of the present invention;

FIG. 3 is a circuit block diagram of the foldable solar energy apparatus according to the present invention;

FIG. 4A is a perspective view of a foldable solar energy apparatus according to a second embodiment of the present invention;

FIG. 4B is a perspective view showing another aspect of the foldable solar energy apparatus according to the second embodiment of the present invention; and

FIG. 5 is a perspective view showing operation of the foldable solar energy apparatus according to the second embodiment of the present invention.

### DETAILED DESCRIPTION OF THE INVENTION

### First Embodiment

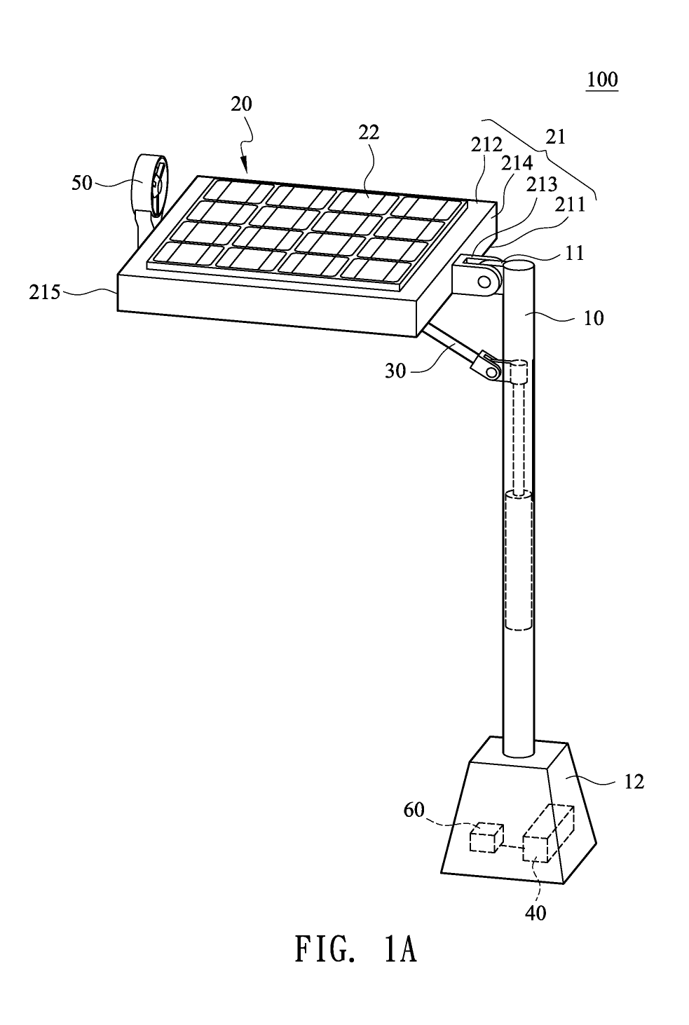

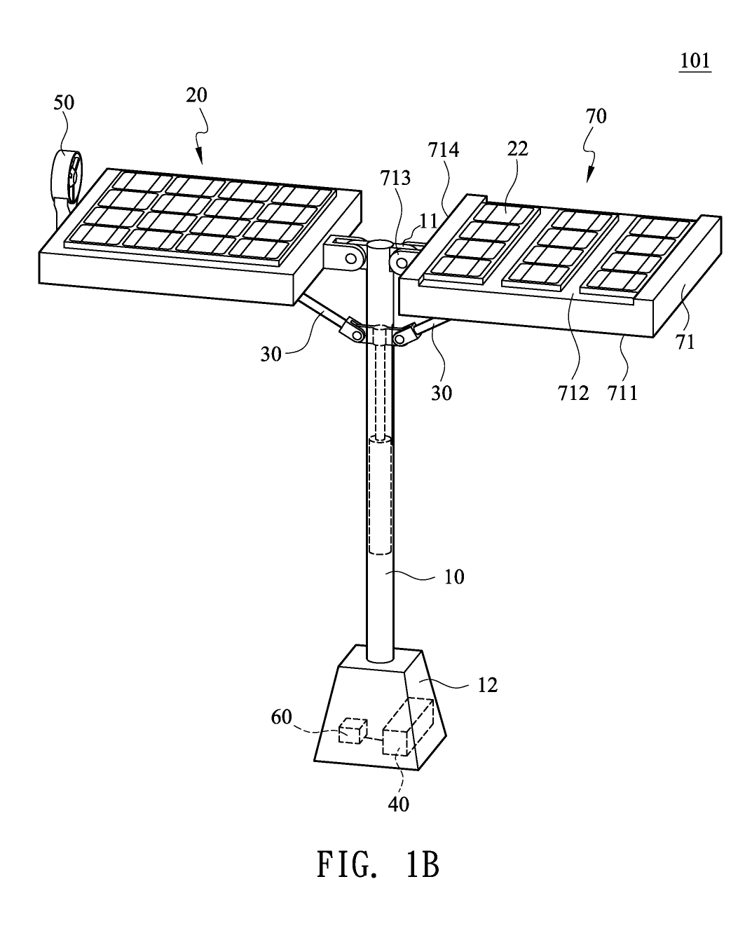

Referring to FIG. 1A, a foldable solar energy apparatus 100 according to a first embodiment of the present invention includes a frame 10, at least one first solar energy module 20, an actuation module 30, and a power module 40.

As shown in FIG. 1A, the frame 10 includes at least one first pivot unit 11 coupled to a top portion of the frame 10. The frame 10 further includes a base 12 formed at a bottom portion of the frame 10, thus allowing the power module 40 to be provided in the base 12.

As shown in FIG. 1A, the first solar energy module 20 includes a first holder 21 and at least one photovoltaic panel 22. The first holder 21 has a first surface 211 and a second surface 212 and includes a second pivot unit 213.

As shown in FIG. 1A, the second surface 212 of the first holder 21 is opposite the first surface 211. The photovoltaic panel 22 is coupled to the second surface 212. The second pivot unit 213 is provided at a first lateral surface 214 of the first holder 21, wherein the first lateral surface 214 is a lateral surface adjacent to the first pivot unit 11 so as for the second pivot unit 213 to be rotatably coupled to the first pivot unit 11 of the frame 10.

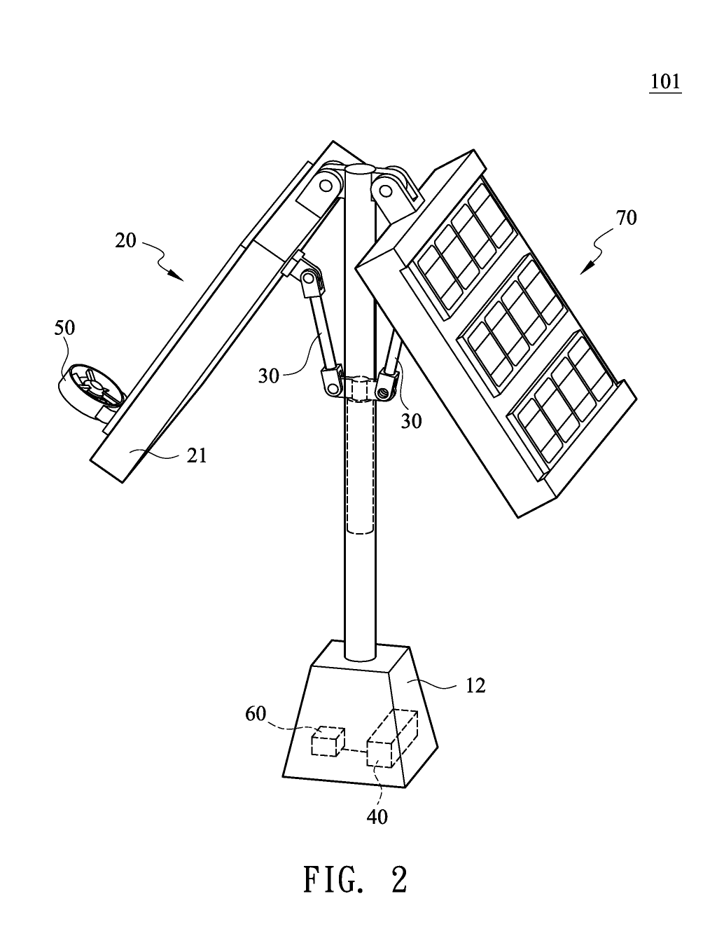

As shown in FIG. 1A, the actuation module 30 is provided at the frame 10 and connected to the first surface 211, thus allowing the first holder 21 to move between a first position and a second position. The first position is the position in which the first solar energy module 20 receives sunlight during normal operation, as shown in FIG. 1A and FIG. 1B. The second position is the position in which the first solar energy module 20, after being rotated and collapsed, has a reduced wind load area, as shown in FIG. 2. More specifically, the actuation module 30 can pull the first holder 21 such that, with the first pivot unit 11 and the second pivot unit 213 serving jointly as a fulcrum, the first holder 21 is rotated from the first position and to second position, thereby collapsing the first solar energy module 20.

The actuation module 30 is a hydraulic device or a pneumatic device. Therefore, even if the first solar energy module 20 is provided with a large-area photovoltaic panel 22, the actuation module 30 can still move the heavy large-area photovoltaic panel 22 easily.

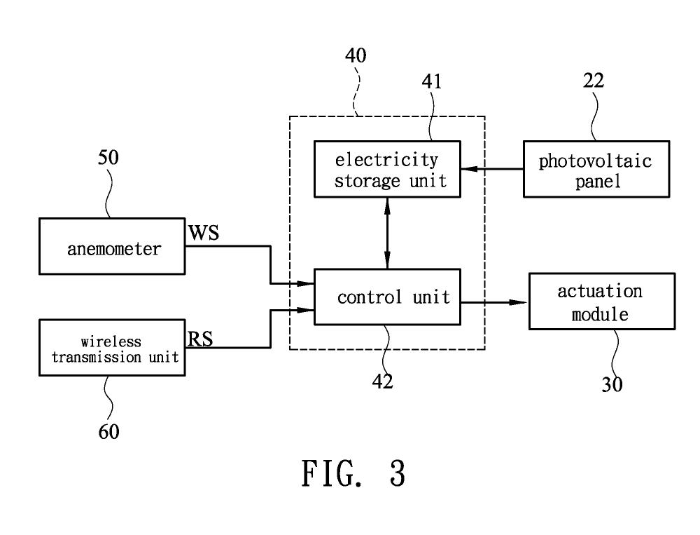

Referring to FIG. 3, the power module 40 includes an electricity storage unit 41 and a control unit 42. The electricity storage unit 41 is electrically connected to the photovoltaic panel 22 so as to store electricity. The control unit 42 is connected in electric signal communication with the electricity storage unit 41 so as to control charging/discharging of the electricity storage unit 41. Thus, the electricity storage device 41 is prevented from having a shortened service life which may otherwise result from the electricity storage device 41 being overcharged. The control unit 42 is also configured for driving the actuation module 30 such that the actuation module 30 moves the first holder 21 according to instructions from the control unit 42, as shown in FIG. 2.

With reference to FIG. 1A to FIG. 3, each of the solar energy apparatuses 100, 101 further includes an anemometer 50. The anemometer 50 is coupled to a second lateral surface 215 of the first holder 21. The second lateral surface 215 is opposite the first lateral surface 214; in other words, the second lateral surface 215 is a lateral surface facing away from the frame 10. The anemometer 50 generates a wind signal WS containing such information as wind direction and Beaufort scale, thus allowing the control unit 42 to drive the actuation module 30 according to the wind signal WS.

For example, the anemometer 50 detects the Beaufort scale around the solar energy apparatus 100, 101 at any time so as to generate the wind signal WS. If the wind signal WS indicates that wind is growing stronger, the control unit 42 will immediately drive the actuation module 30 into operation. As a result, the first holder 21 will be moved from the first position to the second position to collapse the first solar energy module 20 and reduce its wind load area, thereby preventing the first solar energy module 20 from being damaged by strong wind.

As shown in FIG. 1A through FIG. 3, each of the solar energy apparatuses 100, 101 further includes a wireless transmission unit 60. The wireless transmission unit 60 is provided in the frame 10 and preferably in the base 12. The wireless transmission unit 60 is configured for receiving a remote control signal RS. Thus, the control unit 42 can drive the actuation module 30 according to the remote control signal RS as well, allowing the folding of the solar energy apparatuses 100, 101 to be controlled from a distance. Moreover, the wireless transmission unit 60 also enables simultaneous remote control over a large number of solar energy apparatuses 100, 101 such that all the solar energy apparatus 100, 101 can be folded within a short time and thus prevented from damage caused by abrupt weather changes.

Referring to FIG. 1B, the solar energy apparatus 101 further includes a second solar energy module 70. The second solar energy module 70 includes a second holder 71 and at least one photovoltaic panel 22. The second holder 71 has a third surface 711 and a fourth surface 712 and includes a third pivot unit 713.

As shown in FIG. 1B, the third surface 711 of the second holder 71 is connected to the actuation module 30 while the fourth surface 712 is opposite the third surface 711. The second holder 71 further has a recess such that the fourth surface 712 is a bottom surface of the recess. The at least one photovoltaic panel 22 of the second solar energy module 70 is coupled to the fourth surface 712. The second solar energy module 70 may include a plurality of photovoltaic panels 22, as shown in FIG. 1B, or a single large-area photovoltaic panel 22 (not shown), thereby increasing the efficiency of solar energy absorption. Like the second holder 71, the first holder 21 may also have a recess for accommodating the photovoltaic panel 22.

The third pivot unit 713 is provided at a third lateral surface 714 of the second holder 71, wherein the third lateral surface 714 is a lateral surface adjacent to the frame 10, thus allowing the third pivot unit 713 to be rotatably coupled to the corresponding first pivot unit 11 of the frame 10.

When the actuation module 30 is driven by the control unit 42, the first solar energy module 20 and the second solar energy module 70 are simultaneously moved from their respective first positions to their respective second positions, as shown in FIG. 2. Thus, the first solar energy module 20 and the second solar energy module 70 are protected from being damaged by any abrupt weather changes.

### Second Embodiment

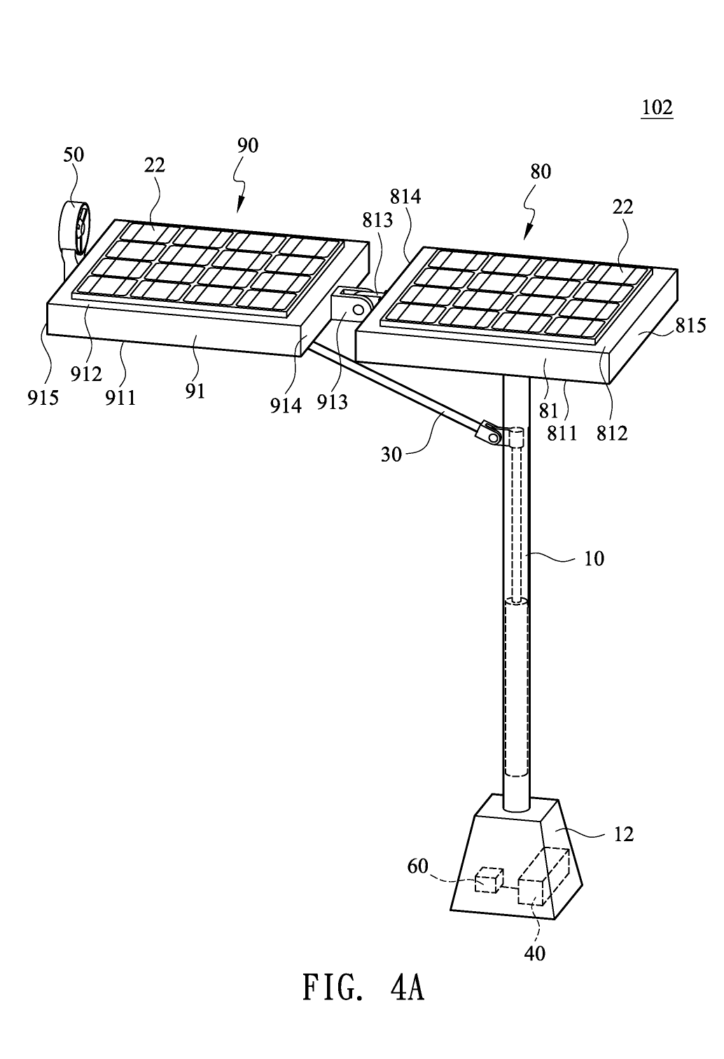

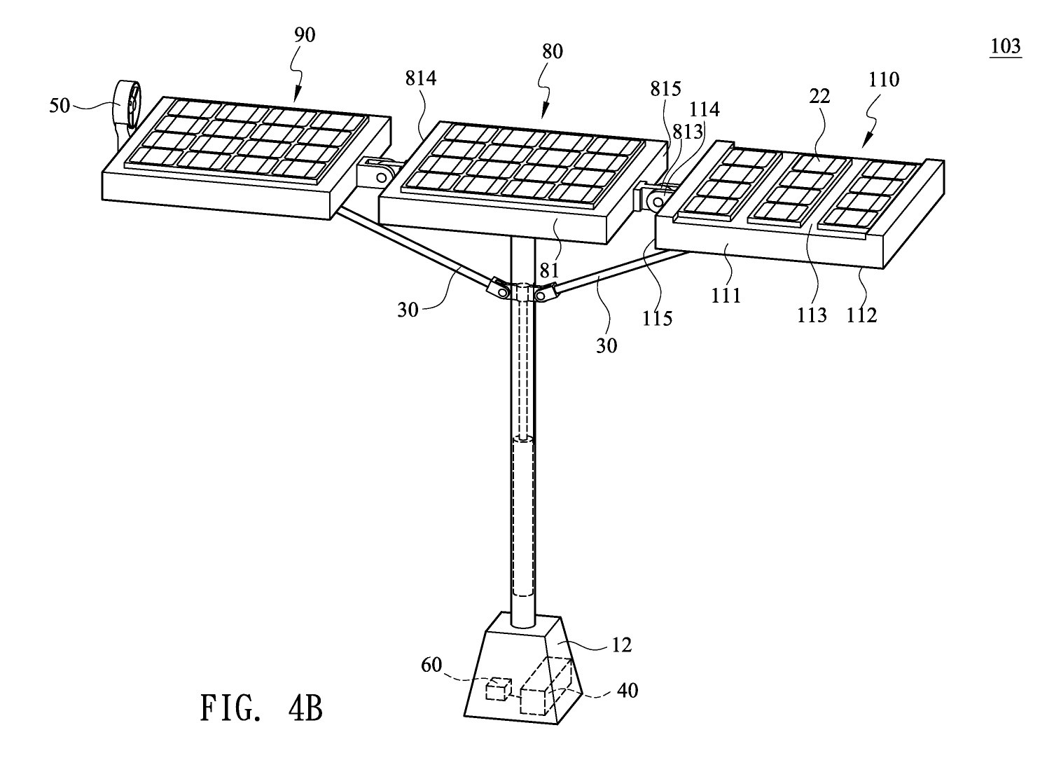

Referring to FIG. 4A, a foldable solar energy apparatus 102 according to a second embodiment of the present invention includes a frame 10, a third solar energy module 80, a fourth solar energy module 90, an actuation module 30, and a power module 40.

As shown in FIG. 4A, the third solar energy module 80 includes a third holder 81 and at least one photovoltaic panel 22. The third holder 81 has a fifth surface 811 and a sixth surface 812 and includes at least one fourth pivot unit 813.

As shown in FIG. 4A, the fifth surface 811 of the third holder 81 is coupled to a top portion of the frame 10. The frame 10 further includes a base 12 formed at a bottom portion of the frame 10 so as for the power module 40 to be provided in the base 12.

As shown in FIG. 4A, the sixth surface 812 of the third holder 81 is opposite the fifth surface 811, and the photovoltaic panel 22 of the third solar energy module 80 is coupled to the sixth surface 812. The at least one fourth pivot unit 813 is provided at a fourth lateral surface 814 of the third holder 81. Alternatively, as shown in FIG. 4B, the fourth pivot units 813 are provided at the fourth lateral surface 814 and a fifth lateral surface 815 of the third holder 81, respectively. The fourth lateral surface 814 and the fifth lateral surface 815 are two opposite lateral surfaces of the third holder 81.

As shown in FIG. 4A, the fourth solar energy module 90 includes a fourth holder 91 and at least one photovoltaic panel 22. The fourth holder 91 has a seventh surface 911 and an eighth surface 912 and includes a fifth pivot unit 913.

As shown in FIG. 4A, the eighth surface 912 of the fourth holder 91 is opposite the seventh surface 911, and the photovoltaic panel 22 of the fourth solar energy module 90 is coupled to the eighth surface 912. The fifth pivot unit 913 is provided at a sixth lateral surface 914 of the fourth holder 91, wherein the sixth lateral surface 914 is a lateral surface adjacent to the third holder 81 so as for the fifth pivot unit 913 to be rotatably coupled to the fourth pivot unit 813 of the third holder 81.

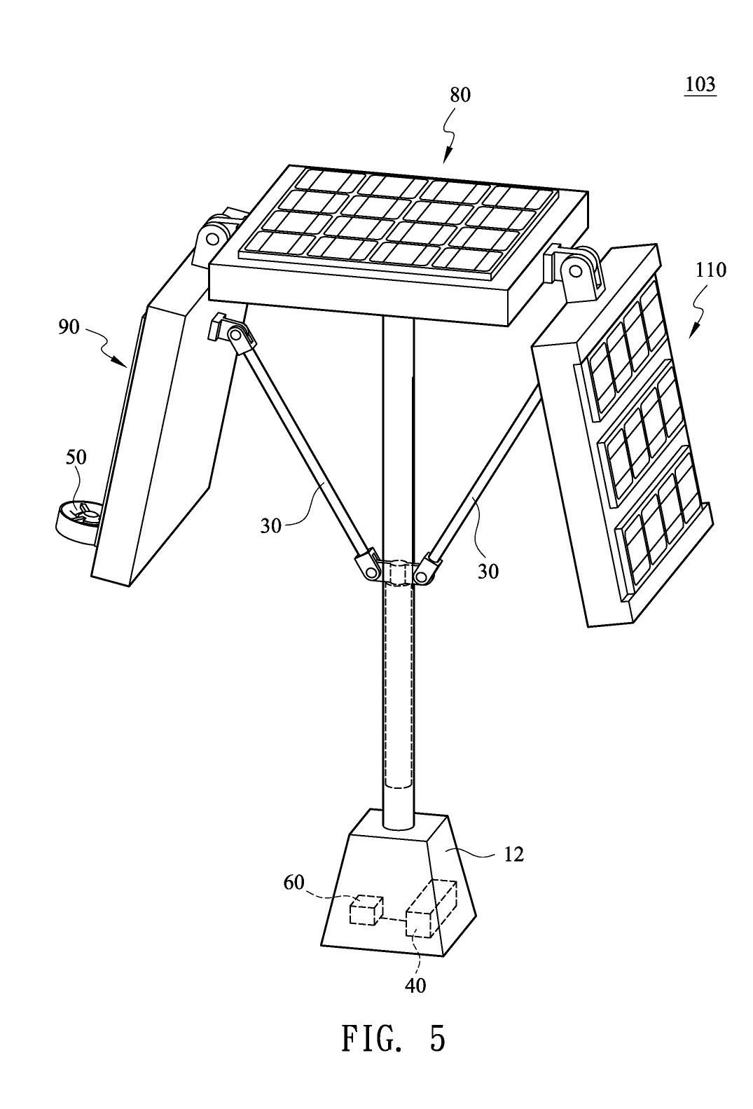

As shown in FIG. 4A, the actuation module 30 is provided at the frame 10 and connected to the seventh surface 911, thus allowing the fourth holder 91 to move between a first position and a second position. The first position is the position in which the fourth solar energy module 90 receives sunlight during normal operation, as shown in FIG. 4A and FIG. 4B. The second position is the position in which the fourth solar energy module 90, after being rotated, has a reduced wind load area, as shown in FIG. 5. More specifically, when pulled by the actuation module 30, the fourth holder 91 can be rotated on a fulcrum defined by the fourth pivot unit 813 and the fifth pivot unit 913, so as to move from the first position to the second position, thereby collapsing the fourth solar energy module 90.

The actuation module 30 is a hydraulic device or a pneumatic device. Therefore, even if the fourth solar energy module 90 includes a large-area photovoltaic panel 22, the actuation module 30 is still capable of moving the weighty large-area photovoltaic panel 22 easily.

With reference to FIG. 3, the power module 40 includes an electricity storage unit 41 and a control unit 42. The electricity storage unit 41 is electrically connected to the photovoltaic panels 22 so as to store electricity. The control unit 42 is connected in electric signal communication with the electricity storage unit 41 so as to control charging/discharging of the electricity storage unit 41. Thus, the electricity storage device 41 will not have a shortened service life which may otherwise result from the electricity storage device 41 being overcharged. Furthermore, the control unit 42 is configured for driving the actuation module 30 such that the actuation module 30 moves the fourth holder 91 according to instructions from the control unit 42.

As shown in FIG. 3 through FIG. 5, each of the solar energy apparatuses 102, 103 further includes an anemometer 50. The anemometer 50 is coupled to a seventh lateral surface 915 of the fourth holder 91. The seventh lateral surface 915 is opposite the sixth lateral surface 914; in other words, the seventh lateral surface 915 is a lateral surface facing away from the third holder 81. The anemometer 50 generates a wind signal WS containing information such as wind direction, Beaufort scale, and so on, thus allowing the control unit 42 to drive the actuation module 30 according to the wind signal WS.

For example, the anemometer 50 detects the Beaufort scale around the solar energy apparatus 102, 103 at any time so as to generate the wind signal WS. If the wind signal WS indicates an increase of wind, the control unit 42 will drive the actuation module 30 into operation at once. As a result, the fourth holder 91 will be moved from the first position to the second position to collapse the fourth solar energy module 90 and reduce its wind load area, thereby preventing the fourth solar energy module 90 from being damaged by strong wind.

As shown in FIG. 3 through FIG. 5, each of the solar energy apparatuses 102, 103 further includes a wireless transmission unit 60. The wireless transmission unit 60 is provided in the frame 10 or in the base 12. The wireless transmission unit 60 is configured for receiving a remote control signal RS. Hence, the control unit 42 can also drive the actuation module 30 according to the remote control signal RS, thereby enabling remote control of the folding of the solar energy apparatuses 102, 103. Besides, the wireless transmission unit 60 also enables simultaneous remote control over a large number of solar energy apparatuses 102, 103 such that all the solar energy apparatus 102, 103 can be folded within a short time and thus prevented from damage caused by abrupt weather changes.

As shown in FIG. 4B, the solar energy apparatus 103 further includes a fifth solar energy module 110 which includes a fifth holder 111 and at least one photovoltaic panel 22. The fifth holder 111 has a ninth surface 112 and a tenth surface 113 and includes a sixth pivot unit 114.

As shown in FIG. 4B, the ninth surface 112 of the fifth holder 111 is connected to the actuation module 30, and the tenth surface 113 is opposite the ninth surface 112. In addition, the fifth holder 111 has a recess such that the tenth surface 113 is a bottom surface of the recess. Meanwhile, the at least one photovoltaic panel 22 of the fifth solar energy module 110 is coupled to the tenth surface 113. The fifth solar energy module 110 may include a plurality of photovoltaic panels 22, as shown in FIG. 4B, or a single large-area photovoltaic panel 22 (not shown), thereby enhancing the efficiency of solar energy absorption. Like the fifth holder 111, the holders 91, 81 may also have recesses for accommodating their respective photovoltaic panels 22.

The sixth pivot unit 114 is provided at an eighth lateral surface 115 of the fifth holder 111, wherein the eighth lateral surface 115 is a lateral surface adjacent to the third holder 81 so as for the sixth pivot unit 114 to be rotatably coupled to the corresponding fourth pivot unit 813 of the third holder 81.

When the actuation module 30 is driven by the control unit 42, the fourth solar energy module 90 and the fifth solar energy module 110 are moved simultaneously from their respective first positions to their respective second positions; in other words, the fourth solar energy module 90 and the fifth solar energy module 110 are moved from the positions in which they receive sunlight during normal operation to the positions in which they have reduced wind load areas, as shown in FIG. 5. Thus, the fourth solar energy module 90 and the fifth solar energy module 110 are protected from being damaged by any abrupt changes in weather conditions.

The foregoing embodiments are illustrative of the characteristics of the present invention so as to enable a person skilled in the art to understand the disclosed subject matter and implement the present invention accordingly. The embodiments, however, are not intended to restrict the scope of the present invention. Hence, all equivalent modifications and variations made in the foregoing embodiments without departing from the spirit and principle of the present invention should fall within the scope of the appended claims.

What is claimed is:

1. A foldable solar energy apparatus, comprising:
a frame comprising at least a first pivot unit coupled to a top portion of the frame;
at least a first solar energy module comprising:
a first holder having a first surface and a second surface opposite the first surface, the first holder comprising a second pivot unit which is provided at a first lateral surface of the first holder and is rotatably coupled to a corresponding one of the at least a first pivot unit; and
at least a photovoltaic panel coupled to the second surface;
an actuation module provided at the frame and connected to the first surface of each said first holder so as for each said first holder to move between a first position and a second position; and
a power module comprising:
an electricity storage unit electrically connected to the at least a photovoltaic panel of each said first solar energy module so as to store electricity; and
a control unit connected in electric signal communication with the electricity storage unit so as to control charging/discharging of the electricity storage unit and drive the actuation module.

2. The solar energy apparatus of claim 1, wherein the frame further comprises a base formed at a bottom portion of the frame, the power module being provided in the base.

3. The solar energy apparatus of claim 1, further comprising an anemometer coupled to a second lateral surface of a said first holder wherein the anemometer generates a wind signal so as for the control unit to drive the actuation module according to the wind signal.

4. The solar energy apparatus of claim 1, further comprising a wireless transmission unit provided at the frame, wherein the wireless transmission unit receives a remote control signal so as for the control unit to drive the actuation module according to the remote control unit.

5. The solar energy apparatus of claim 1, further comprising a second solar energy module comprising:
a second holder having a third surface connected to the actuation module and a fourth surface opposite the third surface, the second holder comprising a third pivot unit which is provided at a third lateral surface of the second holder and is rotatably coupled to a corresponding one of the at least a first pivot unit; and
at least a photovoltaic panel coupled to the fourth surface.

6. A foldable solar energy apparatus, comprising:
a frame;
a third solar energy module comprising:
a third holder having a fifth surface coupled to a top portion of the frame and a sixth surface opposite the fifth surface, the third holder comprising at least a fourth pivot unit provided at a fourth lateral surface and a fifth lateral surface of the third holder, respectively, wherein the fourth lateral surface is opposite the fifth lateral surface; and
at least a photovoltaic panel coupled to the sixth surface;
a fourth solar energy module comprising:
a fourth holder having a seventh surface and an eighth surface opposite the seventh surface, the fourth holder comprising a fifth pivot unit which is provided at a sixth lateral surface of the fourth holder and is rotatably coupled to a corresponding one of the at least a fourth pivot unit; and
at least a photovoltaic panel coupled to the eighth surface;
an actuation module provided at the frame and connected to the seventh surface so as for the fourth holder to move between a first position and a second position; and
a power module comprising:
an electricity storage unit electrically connected to the at least a photovoltaic panel of the third solar energy module and the at least a photovoltaic panel of the fourth solar energy module so as to store electricity; and
a control unit connected in electric signal communication with the electricity storage unit so as to control charging/discharging of the electricity storage unit and drive the actuation module.

7. The solar energy apparatus of claim 6, wherein the frame further comprises a base formed at a bottom portion of the frame, the power module being provided in the base.

8. The solar energy apparatus of claim 6, further comprising an anemometer coupled to a seventh lateral surface of the fourth holder, wherein the anemometer generates a wind signal so as for the control unit to drive the actuation module according to the wind signal.

9. The solar energy apparatus of claim 6, further comprising a wireless transmission unit provided at the frame, wherein the wireless transmission unit receives a remote control signal so as for the control unit to drive the actuation module according to the remote control unit.

10. The solar energy apparatus of claim 6, further comprising a fifth solar energy module comprising:
a fifth holder having a ninth surface connected to the actuation module and a tenth surface opposite the ninth surface, the fifth holder comprising a sixth pivot unit which is provided at an eighth lateral surface of the fifth holder and is rotatably coupled to a corresponding one of the at least a fourth pivot unit; and
at least a photovoltaic panel coupled to the tenth surface.
